(19) United States
(12) Patent Application Publication
(10) Pub. No.: US 2010/0270599 A1
(43) Pub. Date: Oct. 28, 2010

(54) TRANSISTOR STRUCTURE WITH HIGH RELIABILITY AND METHOD FOR MANUFACTURING THE SAME

(75) Inventors: CHIH-CHIANG KUO, TAIPEI CITY (TW); CHIN-LIEN LIN, TAICHUNG CITY (TW)

Correspondence Address: ROSENBERG, KLEIN & LEE, 3458 ELLICOTT CENTER DRIVE-SUITE 101, ELLICOTT CITY, MD, 21043, US

(73) Assignee: INOTERA MEMORIES, INC., TAOYUAN COUNTY (TW)

(21) Appl. No.: 12/542,214

(22) Filed: Aug. 17, 2009

(30) Foreign Application Priority Data
Apr. 24, 2009 (TW) 98113602

(51) Int. Cl. H01L 29/78; H01L 21/28; H01L 21/336

(52) U.S. Cl. 257/288; 438/585; 438/197; 257/E29.255; 257/E21.19; 257/E21.409

(57) ABSTRACT

A transistor structure with high reliability includes a substrate unit, a solid ozone boundary layer, a gate oxide layer and a gate electrode. In addition, the substrate unit has a substrate body, a source electrode exposed on a top surface of the substrate body, and a drain electrode exposed on the top surface of the substrate body and separated from the source electrode by a predetermined distance. The solid ozone boundary layer is gradually grown on the top surface of the substrate body by continually mixing gaseous ozone into deionized water under 40˜95□, and the solid ozone boundary layer is formed between the source electrode and the drain electrode and formed on the substrate body. The gate oxide layer is formed on a top surface of the solid ozone boundary layer. The gate electrode is formed on a top surface of the gate oxide layer.

### BACKGROUND OF THE INVENTION

1. Field of the Invention

The present invention relates to a transistor structure and a method for manufacturing the same, in particular, to a transistor structure with high reliability and a method for manufacturing the same.

2. Description of Related Art

With the scaling of integrated circuits, applications require an increasingly faster speed. This puts a requirement on the metal-oxide-semiconductor (MOS) devices, demanding that the MOS devices switch faster. As is known in the art, to increase the speed of MOS devices, high dielectric constant values (k values) of the gate dielectrics are desired. Since conventional silicon oxide, which has a k value of about 3.9, cannot satisfy such a requirement, high-k dielectric materials, which include oxides, nitrides, and oxynitrides, are increasingly used.

High-k dielectric materials, however, have high trap densities, and thus cannot be used close to the channel regions of the MOS devices. A stacked gate dielectric scheme has been introduced to accommodate the benefit of the high-k materials and conventional oxides that have low trap densities. Typically, a base oxide layer is formed on the channel region, followed by the formation of a high-k material on the base oxide layer. The stacked layers function as a gate dielectric layer.

A shortcoming with the existing stacked gate dielectric layer is the reduction of effective oxide thickness (EOT). In a conventional base oxide formation process, diluted HF is used for removing native oxide on the surface of the semiconductor substrate. Standard clean processes, which typically include a standard clean process 1 and a standard clean process 2, can also be used for cleaning the surface of the substrate. A native oxide may then be formed on the clean surface of the substrate. Using this method, the thickness of the base oxide layer can be lowered to between about 9 Å and about 10 Å. The effective oxide thickness (EOT) of the stacked layer, which includes the EOT of the base oxide layer and about 30 Å of a high-k dielectric layer, may be lowered to about 14 Å and about 15 Å accordingly. Further lowering of the EOT of the gate dielectric, however, has been limited, mainly due to the thickness of the base oxide layer. This is because although reducing the thickness of the base oxide layer can cause the reduction of the EOT, as is commonly perceived, further reduction of the thickness of the base oxide is not feasible. One of the reasons is that the surface condition of the traditionally formed oxides is thickness dependent, and the surface condition affects the quality of the subsequently formed high-k film. A base oxide layer typically needs to have a certain thickness in order to have a substantially smooth surface.

Moreover, refereeing to FIG. 1, the prior art provides a simple transistor structure including: a substrate unit 1, a gate oxide layer 3 and a gate electrode 4. In addition, the substrate unit 1 has a substrate body 10, a source electrode 11 exposed on a top surface of the substrate body 10, and a drain electrode 12 exposed on the top surface of the substrate body 10 and separated from the source electrode 11 by a predetermined distance. The gate oxide layer 3 is formed on the top surface of the substrate body 10 and between the source electrode 11 and the drain electrode 12. The gate electrode 4 is formed on a top surface of the gate oxide layer 3. However, the current velocity (e−) from the source electrode 11 to the drain electrode 12 always cannot be increased effectively by using the simple transistor structure of the prior art. In addition, the simple transistor structure of the prior art has the following deficiencies: (1) poor roughness (RMS) on silicon surface, (2) low density oxide interface, (3) high silicon loss, (4) poor gate oxide reliability, and (5) poor efficiency particle removal rate.

### SUMMARY OF THE INVENTION

In view of the aforementioned issues, the present invention provides a transistor structure with high reliability and a method for manufacturing the same. The prevent invention can manufacture a solid ozone boundary layer with high concentration in order to increase current velocity from a source electrode to a drain electrode.

To achieve the above-mentioned objectives, the present invention provides a transistor structure with high reliability, including: a substrate unit, a solid ozone boundary layer, a gate oxide layer and a gate electrode. In addition, the substrate unit has a substrate body, a source electrode exposed on a top surface of the substrate body, and a drain electrode exposed on the top surface of the substrate body and separated from the source electrode by a predetermined distance. The solid ozone boundary layer is gradually grown on the top surface of the substrate body by continually mixing gaseous ozone into deionized water under 40˜95□, and the solid ozone boundary layer is formed between the source electrode and the drain electrode and formed on the substrate body. The gate oxide layer is formed on a top surface of the solid ozone boundary layer. The gate electrode is formed on a top surface of the gate oxide layer.

To achieve the above-mentioned objectives, the present invention provides a method for manufacturing a transistor structure with high reliability, including: providing a substrate unit, and the substrate unit having a substrate body, a source electrode exposed on a top surface of the substrate body, and a drain electrode exposed on the top surface of the substrate body and separated from the source electrode by a predetermined distance; continually pouring deionized water on the top surface of the substrate unit; continually mixing gaseous ozone into the deionized water under 40˜95□; gradually forming a solid ozone layer on the top surface of the substrate unit by the above-mentioned mixture of the gaseous ozone and the deionized water; forming a gate oxidation material layer on a top surface of the solid ozone layer; forming a gate electrode material layer on a top surface of the gate oxidation material layer; and then removing one part of the solid ozone layer, one part of the gate oxidation material layer and one part of gate electrode material layer that are formed above the source electrode and the drain electrode in order to respectively form a solid ozone boundary layer between the source electrode and the drain electrode and on the substrate body, a gate oxide layer being formed on a top surface of the solid ozone boundary layer, and a gate electrode being formed on a top surface of the gate oxide layer.

To achieve the above-mentioned objectives, the present invention provides a method for manufacturing a transistor structure with high reliability, including: providing a substrate unit, and the substrate unit having a substrate body, a source electrode exposed on a top surface of the substrate body, and a drain electrode exposed on the top surface of the substrate body and separated from the source electrode by a predetermined distance; continually pouring deionized water on the top surface of the substrate unit; continually mixing gaseous ozone into the deionized water under 40˜95□; gradually forming a solid ozone layer on the top surface of the substrate unit by the above-mentioned mixture of the gaseous ozone and the deionized water; removing one part of the solid ozone layer to reduce the thickness of the solid ozone layer in order to form a thin solid ozone layer; forming a gate oxidation material layer on a top surface of the thin solid ozone layer; forming a gate electrode material layer on a top surface of the gate oxidation material layer; and then removing one part of the thin solid ozone layer, one part of the gate oxidation material layer and one part of gate electrode material layer that are formed above the source electrode and the drain electrode in order to respectively form a thin solid ozone boundary layer between the source electrode and the drain electrode and on the substrate body, a gate oxide layer being formed on a top surface of the thin solid ozone boundary layer, and a gate electrode being formed on a top surface of the gate oxide layer.

Therefore, the prevent invention can manufacture the solid ozone boundary layer with high concentration by matching the two steps of “continually mixing gaseous ozone into the deionized water under 40˜95□” and “gradually forming a solid ozone layer on the top surface of the substrate unit by the above-mentioned mixture of the gaseous ozone and the deionized water” in order to increase current velocity from the source electrode to the drain electrode. Hence, the present invention can generate the following advantages: (1) low roughness (RMS) on silicon surface, (2) high density oxide interface, (3) low silicon loss, (4) excellent gate oxide reliability and (5) high efficiency particle removal rate.

In order to further understand the techniques, means and effects the present invention takes for achieving the prescribed objectives, the following detailed descriptions and append portioned drawings are hereby referred, such that, through which, the purposes, features and aspects of the present invention can be thoroughly and concretely appreciated; however, the append portioned drawings are merely provided for reference and illustration, without any intention to be used for limiting the present invention.

### BRIEF DESCRIPTION OF THE DRAWINGS

FIG. 1 is a front, schematic view of the simple transistor structure according to the prior art;

FIG. 2 is a flowchart of the method for manufacturing a transistor structure according to the first embodiment of the present invention;

FIG. 2A is a front, schematic view of a solid ozone layer formed on the top surface of the substrate unit, according to the first embodiment of the present invention;

FIG. 2A1 is a perspective, schematic view of the deionized water continually poured on the top surface of the substrate unit, according to the first embodiment of the present invention;

FIG. 2A2 is an enlarged view of A part in FIG. 2A1;

FIG. 2A3 is a curve diagram shown the temperature of continually pouring the deionized water on the top surface of the substrate unit and the concentration of the gaseous ozone, according to the first embodiment of the present invention;

FIG. 2B is a front, schematic view of a gate oxidation material layer formed on a top surface of the solid ozone layer, according to the first embodiment of the present invention;

FIG. 2C is a front, schematic view of a gate electrode material layer formed on a top surface of the gate oxidation material layer, according to the first embodiment of the present invention;

FIG. 2D is a front, schematic view of the transistor structure with high reliability according to the first embodiment of the present invention;

FIG. 3 is a flowchart of the method for manufacturing a transistor structure according to the second embodiment of the present invention;

FIG. 3A is a front, schematic view of a solid ozone layer formed on the top surface of the substrate unit, according to the second embodiment of the present invention;

FIG. 3B is a front, schematic view of one part of the solid ozone layer being removed in order to form a thin solid ozone layer, according to the second embodiment of the present invention;

FIG. 3C is a front, schematic view of a gate oxidation material layer formed on a top surface of the thin solid ozone layer, according to the second embodiment of the present invention;

FIG. 3D is a front, schematic view of a gate electrode material layer formed on a top surface of the gate oxidation material layer, according to the second embodiment of the present invention;

FIG. 3E is a front, schematic view of the transistor structure with high reliability according to the second embodiment of the present invention;

FIG. 4A is a curve diagram of the bulk lifetime of the present invention and the prior art;

FIG. 4B is a curve diagram of the charges contamination in oxide of the present invention and the prior art;

FIG. 4C is a curve diagram of the breakdown voltage of the present invention and the prior art; and

FIG. 4D is a curve diagram of the mobile ions of the present invention and the prior art.

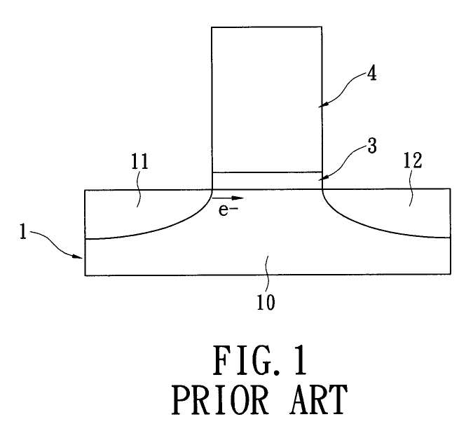

### DETAILED DESCRIPTION OF THE PREFERRED EMBODIMENTS

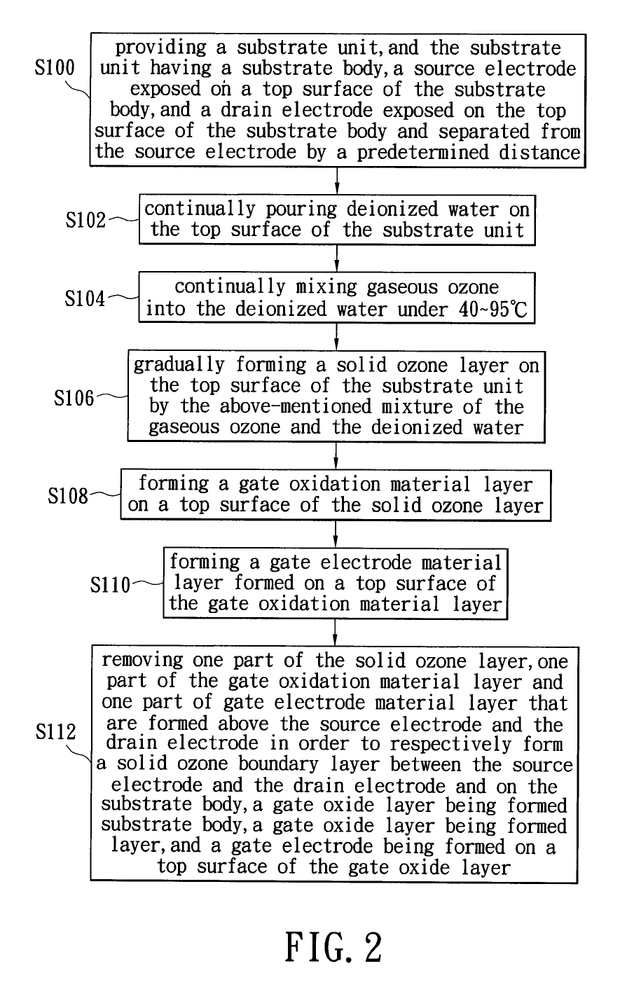

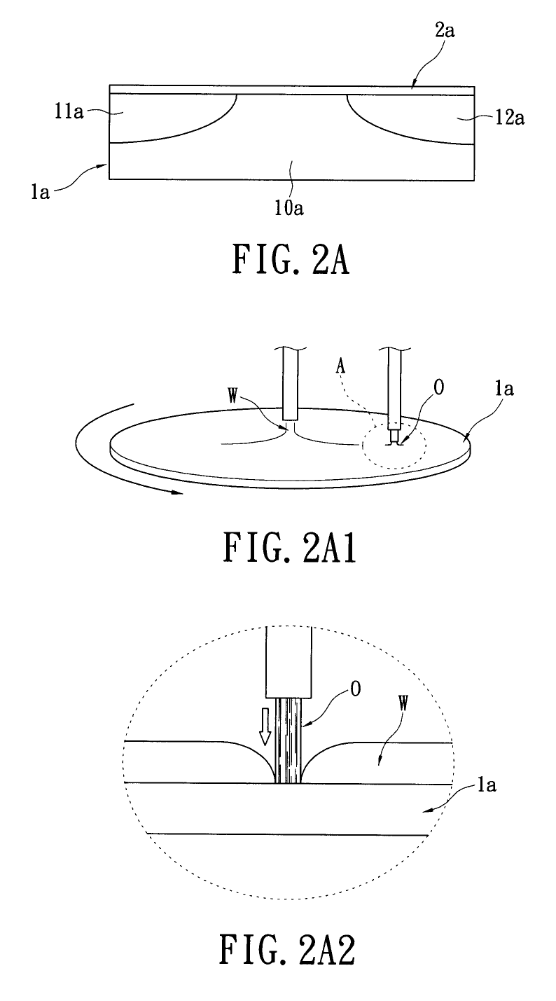

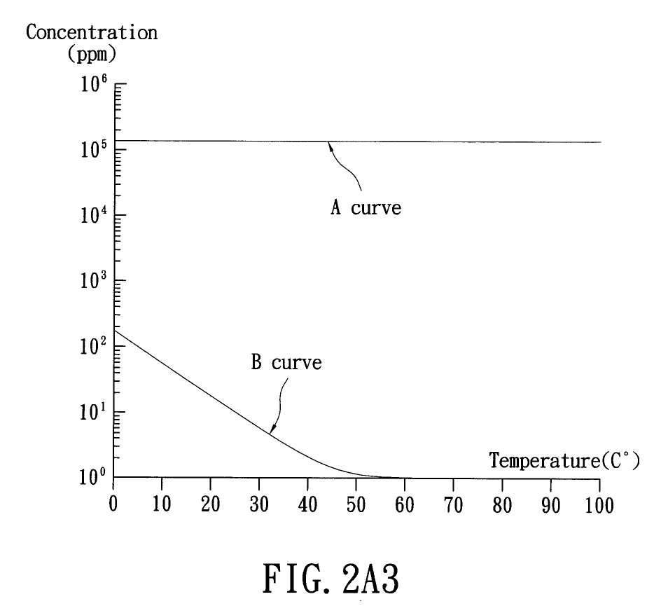

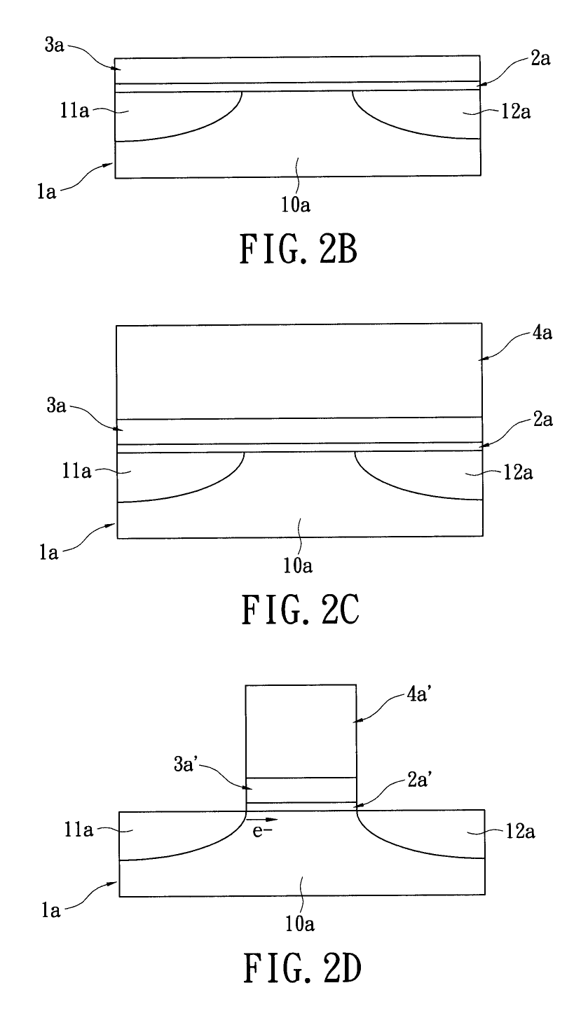

Referring to FIG. 2, the first embodiment of the present invention provides a method for manufacturing a transistor structure with high reliability. The method includes the following steps: providing a substrate unit; continually pouring deionized water on the top surface of the substrate unit; continually mixing gaseous ozone into the deionized water under 40˜95□; gradually forming a solid ozone layer on the top surface of the substrate unit by the above-mentioned mixture of the gaseous ozone and the deionized water; forming a gate oxidation material layer on a top surface of the solid ozone layer; forming a gate electrode material layer on a top surface of the gate oxidation material layer; and then removing one part of the solid ozone layer, one part of the gate oxidation material layer and one part of gate electrode material layer that are formed above a source electrode and a drain electrode of the substrate unit.

Referring to FIGS. 2A to 2D, the detail description of the first embodiment is shown as follows:

The step S100 is that: referring to FIGS. 2 and 2A, providing a substrate unit 1a, and the substrate unit 1a having a substrate body 10a, a source electrode 11a exposed on a top surface of the substrate body 10a, and a drain electrode 12a exposed on the top surface of the substrate body 10a and separated from the source electrode 11a by a predetermined distance.

The step S102 is that: referring to FIGS. 2, 2A and 2A1, continually pouring deionized water (DIW) W on the top surface of the substrate unit 1a. In addition, before the step of continually pouring the deionized water W on the top surface of the substrate unit 1a, chemical substances (not shown) can be mixed in the deionized water W first. Hence, the deionized water W mixed with chemical substances can be continually poured on the top surface of the substrate unit 1a. Moreover, in the first embodiment, the substrate unit 1a can be a wafer, so that the substrate body 10a can be a silicon substrate, and the wafer is continually rotated by itself (the rotation direction is shown as the arrow in FIG. 2A1).

The step S104 is that: referring to FIGS. 2, 2A and 2A1-2A3, continually mixing gaseous ozone O into the deionized water W under 40˜95□ (as shown in FIG. 2A2). In addition, the concentration of the gaseous ozone O does not be reduced according to the increase of the temperature as shown in FIG. 2A3. On the contrary, the concentration of the gaseous ozone O is shown as a stable state (shown as the A curve of FIG. 2A3). However, when the ozone has been mixed with DIW first and the ozone mixed with DIW is poured on the substrate unit, the concentration of the ozone mixed with DIW is reduced according to the increase of the temperature (shown as the B curve of FIG. 2A3).

The step S106 is that: referring to FIGS. 2 and 2A, gradually forming a solid ozone layer 2a on the top surface of the substrate unit 1a by the above-mentioned mixture of the gaseous ozone O and the deionized water W. In other words, when the gaseous ozone O is continually mixed into the deionized water W that is on the substrate unit 1a, the solid ozone layer 2a is gradually grown at the same time. In addition, the growth reaction equation of the solid ozone layer 2a is 3Si+2O₃→3SiO₂.

The step S108 is that: referring to FIGS. 2 and 2B, forming a gate oxidation material layer 3a on a top surface of the solid ozone layer 2a.

The step S110 is that: referring to FIGS. 2 and 2C, forming a gate electrode material layer 4a formed on a top surface of the gate oxidation material layer 3a.

The step S112 is that: referring to FIGS. 2, 2C and 2D, removing one part of the solid ozone layer 2a, one part of the gate oxidation material layer 3a and one part of gate electrode material layer 4a that are formed above the source electrode 11a and the drain electrode 12a in order to respectively form a solid ozone boundary layer 2a′ between the source electrode 11a and the drain electrode 12a and on the substrate body 10a, a gate oxide layer 3a′ being formed on a top surface of the solid ozone boundary layer 2a′, and a gate electrode 4a′ being formed on a top surface of the gate oxide layer 3a′. In addition, the partial solid ozone layer 2a, the partial gate oxidation material layer 3a and the partial gate electrode material layer 4a formed above the source electrode 11a and the drain electrode 12a are removed by etching.

Therefore, referring to FIG. 2D, the first embodiment of the present invention provides a transistor structure with high reliability, including: a substrate unit 1a, a solid ozone boundary layer 2a′, a gate oxide layer 3a′ and a gate electrode 4a′. In addition, the substrate unit 1a has a substrate body 10a, a source electrode 11a exposed on a top surface of the substrate body 10a, and a drain electrode 12a exposed on the top surface of the substrate body 10a and separated from the source electrode 11a by a predetermined distance. The solid ozone boundary layer 2a′ is an interface layer that is gradually grown on the top surface of the substrate body 10a by continually mixing gaseous ozone into deionized water under 40˜95□. Moreover, the growth reaction equation of the solid ozone layer is 3Si+2O₃→3SiO₂, and the solid ozone boundary layer 2a′ is formed between the source electrode 11a and the drain electrode 12a and formed on the substrate body 10a. Furthermore, the gate oxide layer 3a′ is formed on a top surface of the solid ozone boundary layer 2a′, and the gate electrode 4a′ is formed on a top surface of the gate oxide layer 3a′.

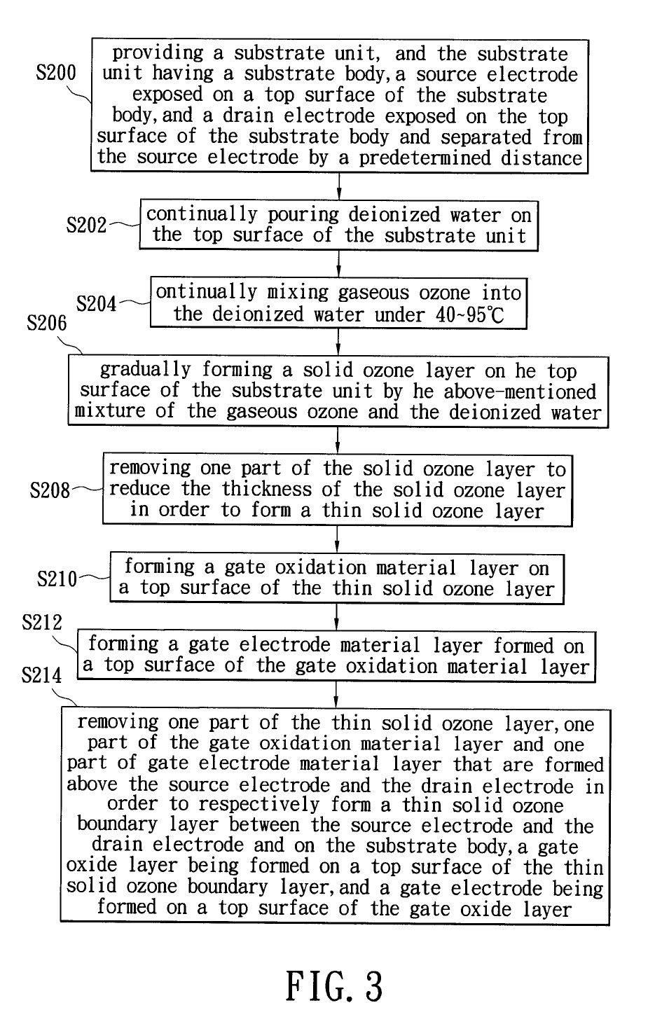

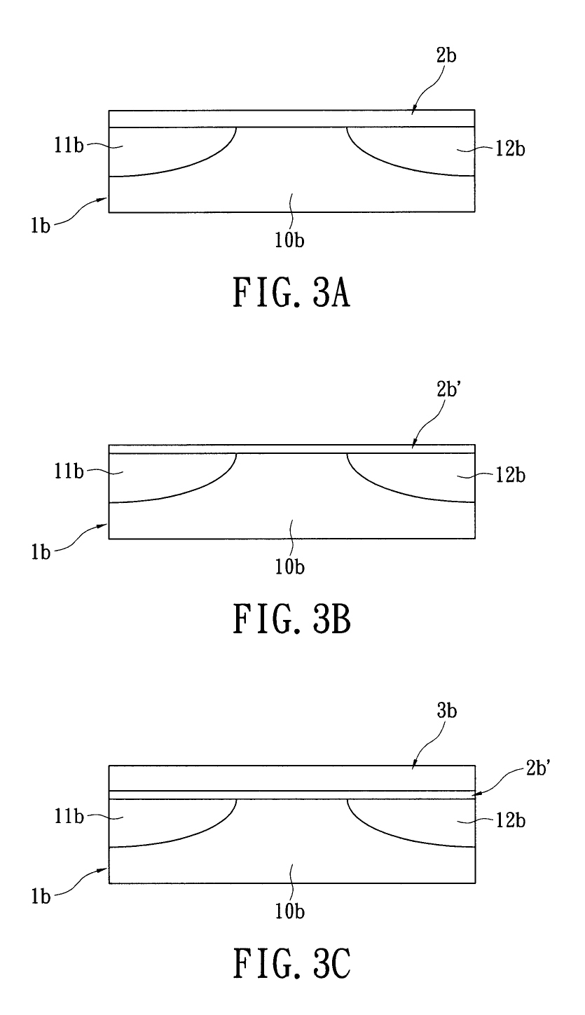

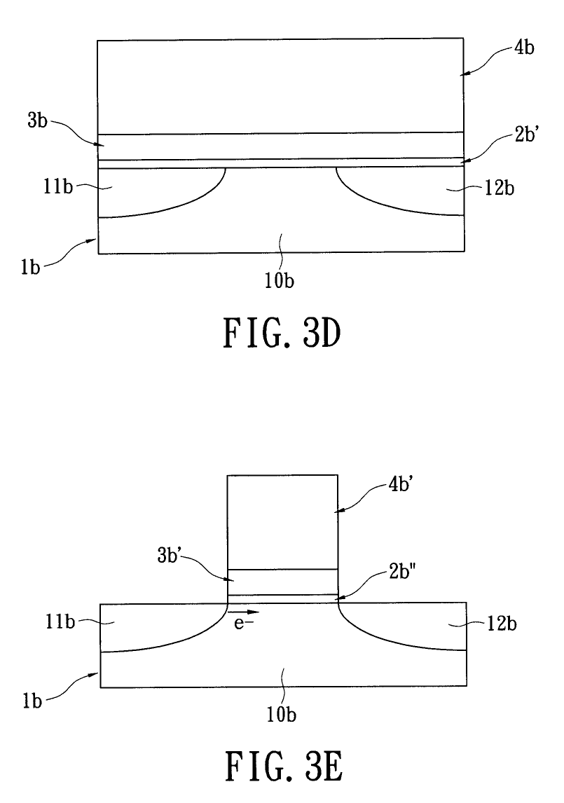

Referring to FIG. 3, the second embodiment of the present invention provides a method for manufacturing a transistor structure with high reliability. The method includes the following steps: providing a substrate unit; continually pouring deionized water on the top surface of the substrate unit; continually mixing gaseous ozone into the deionized water under 40˜95□; gradually forming a solid ozone layer on the top surface of the substrate unit by the above-mentioned mixture of the gaseous ozone and the deionized water; removing one part of the solid ozone layer to reduce the thickness of the solid ozone layer in order to form a thin solid ozone layer; forming a gate oxidation material layer on a top surface of the thin solid ozone layer; forming a gate electrode material layer on a top surface of the gate oxidation material layer; and then removing one part of the thin solid ozone layer, one part of the gate oxidation material layer and one part of gate electrode material layer that are formed above a source electrode and a drain electrode of the substrate unit.

Referring to FIGS. 3A to 3E, the detail description of the second embodiment is shown as follows:

The step S200 is that: referring to FIGS. 3 and 3A, providing a substrate unit 1b, and the substrate unit 1b having a substrate body 10b, a source electrode 11b exposed on a top surface of the substrate body 10b, and a drain electrode 12b exposed on the top surface of the substrate body 10b and separated from the source electrode 11b by a predetermined distance. In addition, the substrate body 10b can be a silicon substrate.

The step S202 is that: referring to FIG. 3, continually pouring deionized water (DIW) on the top surface of the substrate unit 1b. The step S202 is the same as the step S102.

The step S204 is that: referring to FIG. 3, continually mixing gaseous ozone into the deionized water under 40˜95□. The step S204 is the same as the step S104.

The step S206 is that: referring to FIGS. 3 and 3A, gradually forming a solid ozone layer 2b on the top surface of the substrate unit 1b by the above-mentioned mixture of the gaseous ozone and the deionized water. In addition, the growth reaction equation of the solid ozone layer 2b is 3Si+2O₃→3SiO₂.

The step S208 is that: referring to FIGS. 3, 3A and 3B, removing one part of the solid ozone layer 2b to reduce the thickness of the solid ozone layer 2b in order to form a thin solid ozone layer 2b′. In addition, the partial solid ozone layer 2b is removed by etching.

The step S210 is that: referring to FIGS. 3 and 3C, forming a gate oxidation material layer 3b on a top surface of the thin solid ozone layer 2b′.

The step S212 is that: referring to FIGS. 3 and 3D, forming a gate electrode material layer 4b formed on a top surface of the gate oxidation material layer 3b.

The step S214 is that: referring to FIGS. 3 and 3E, removing one part of the thin solid ozone layer 2b′, one part of the gate oxidation material layer 3b and one part of gate electrode material layer 4b that are formed above the source electrode 11b and the drain electrode 12b in order to respectively form a thin solid ozone boundary layer 2b″ between the source electrode 11b and the drain electrode 12b and on the substrate body 10b, a gate oxide layer 3b′ being formed on a top surface of the thin solid ozone boundary layer 2b″, and a gate electrode 4b′ being formed on a top surface of the gate oxide layer 3b′.

Therefore, referring to FIG. 3E, the second embodiment of the present invention provides a transistor structure with high reliability, including: a substrate unit 1b, a thin solid ozone boundary layer 2b″, a gate oxide layer 3b′ and a gate electrode 4b′. In addition, the substrate unit 1b has a substrate body 10b, a source electrode 11b exposed on a top surface of the substrate body 10b, and a drain electrode 12b exposed on the top surface of the substrate body 10b and separated from the source electrode 11b by a predetermined distance. The thin solid ozone boundary layer 2b″ is an interface layer that is gradually grown on the top surface of the substrate body 10b by continually mixing gaseous ozone into deionized water under 40˜95□. Moreover, the growth reaction equation of the solid ozone layer is 3Si+2O₃→3SiO₂, and the thin solid ozone boundary layer 2b″ is formed between the source electrode 11b and the drain electrode 12b and formed on the substrate body 10b. Furthermore, the gate oxide layer 3b′ is formed on a top surface of the thin solid ozone boundary layer 2b″, and the gate electrode 4b′ is formed on a top surface of the gate oxide layer 3b′.

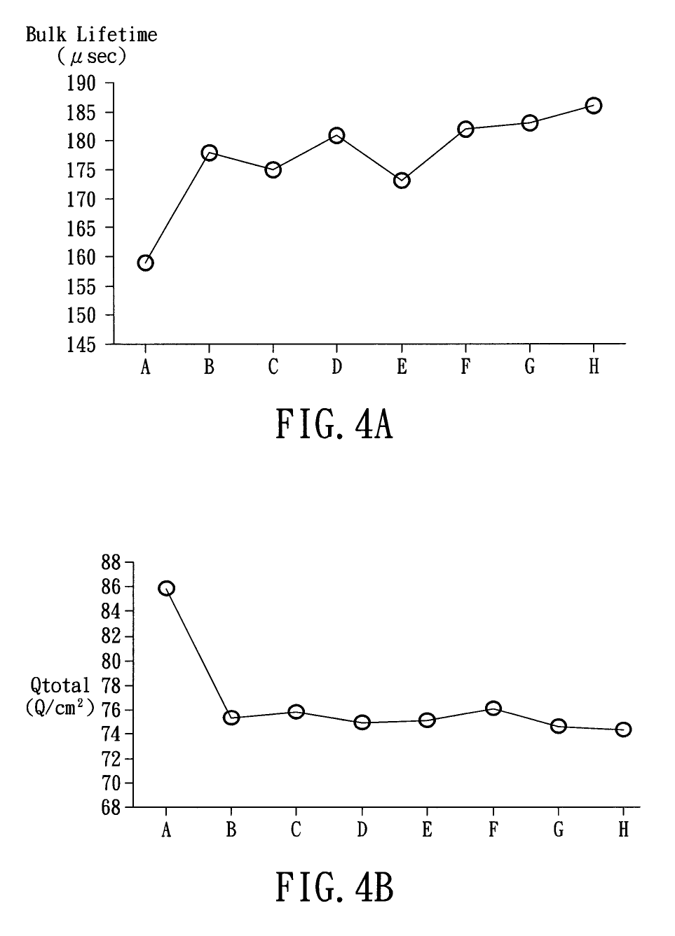

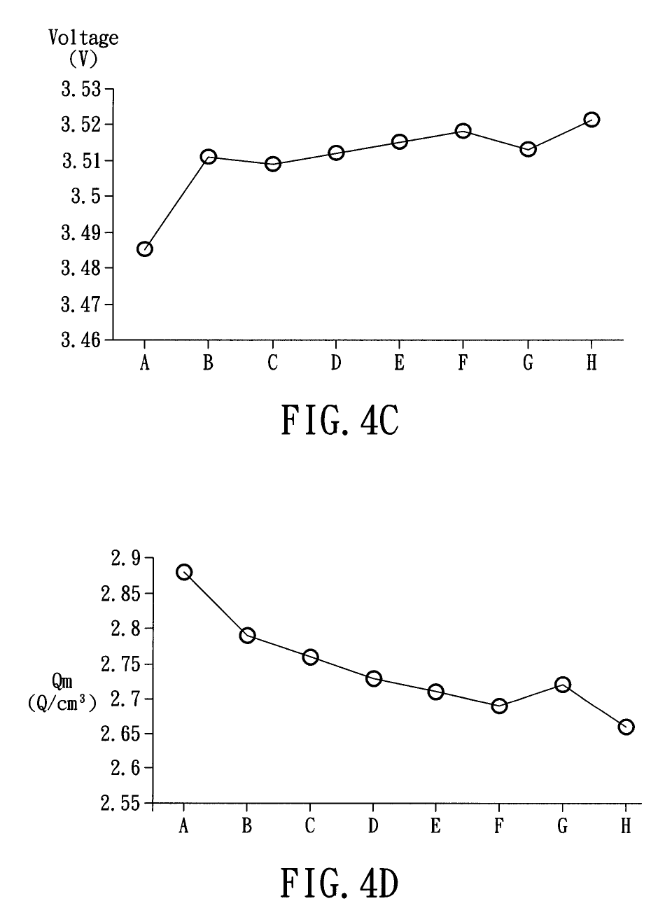

Referring to FIGS. 4A to 4D, the x-axis shows the transistor structure (A) of the prior art and the transistor structures (B, C, D, E, F, G, H) with high reliability of the present invention. Many testing results show that the performance of the present invention is better than that of the prior art. For example:

1. The bulk lifetime (L(μsec)) of present invention is higher than that of the prior art as shown in FIG. 4A.

2. The charges contamination (Qₜₒₜₐₗ(Q/cm²)) in oxide of present invention is lower than that of the prior art as shown in FIG. 4B.

3. The breakdown voltage (Voltage(V)) of present invention is higher than that of the prior art as shown in FIG. 4C.

4. The mobile ions (Qm(Q/cm³)) of present invention are lower than that of the prior art as shown in FIG. 4D.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A transistor structure with high reliability, comprising:
a substrate unit having a substrate body, a source electrode exposed on a top surface of the substrate body, and a drain electrode exposed on the top surface of the substrate body and separated from the source electrode by a predetermined distance;
a solid ozone boundary layer gradually grown on the top surface of the substrate body by continually mixing gaseous ozone into deionized water under 40˜95° wherein the solid ozone boundary layer is formed between the source electrode and the drain electrode and formed on the substrate body;
a gate oxide layer formed on a top surface of the solid ozone boundary layer; and
a gate electrode formed on a top surface of the gate oxide layer.

2. The transistor structure according to claim 1, wherein the substrate body is a silicon substrate.

3. The transistor structure according to claim 1, wherein the growth reaction equation of the solid ozone layer is 3Si+2O₃→3SiO₂.

4. A method for manufacturing a transistor structure with high reliability, comprising:
providing a substrate unit, wherein the substrate unit has a substrate body, a source electrode exposed on a top surface of the substrate body, and a drain electrode exposed on the top surface of the substrate body and separated from the source electrode by a predetermined distance;
continually pouring deionized water on the top surface of the substrate unit;
continually mixing gaseous ozone into the deionized water under 40˜95□;
gradually forming a solid ozone layer on the top surface of the substrate unit by the above-mentioned mixture of the gaseous ozone and the deionized water;
forming a gate oxidation material layer on a top surface of the solid ozone layer;
forming a gate electrode material layer on a top surface of the gate oxidation material layer; and
removing one part of the solid ozone layer, one part of the gate oxidation material layer and one part of gate electrode material layer that are formed above the source electrode and the drain electrode in order to respectively form a solid ozone boundary layer between the source electrode and the drain electrode and on the substrate body, a gate oxide layer being formed on a top surface of the solid ozone boundary layer, and a gate electrode being formed on a top surface of the gate oxide layer.

5. The method according to claim 4, wherein the substrate body is a silicon substrate.

6. The method according to claim 4, wherein the growth reaction equation of the solid ozone layer is 3Si+2O₃→3SiO₂.

7. The method according to claim 4, wherein the partial solid ozone layer, the partial gate oxidation material layer and the partial gate electrode material layer formed above the source electrode and the drain electrode are removed by etching.

8. The method according to claim 4, wherein before the step of continually pouring the deionized water on the top surface of the substrate unit, the method further comprises mixing chemical substances in the deionized water.

9. A method for manufacturing a transistor structure with high reliability, comprising:
providing a substrate unit, wherein the substrate unit has a substrate body, a source electrode exposed on a top surface of the substrate body, and a drain electrode exposed on the top surface of the substrate body and separated from the source electrode by a predetermined distance;
continually pouring deionized water on the top surface of the substrate unit;
continually mixing gaseous ozone into the deionized water under 40˜95°;
gradually forming a solid ozone layer on the top surface of the substrate unit by the above-mentioned mixture of the gaseous ozone and the deionized water;
removing one part of the solid ozone layer to reduce the thickness of the solid ozone layer in order to form a thin solid ozone layer;
forming a gate oxidation material layer on a top surface of the thin solid ozone layer;
forming a gate electrode material layer on a top surface of the gate oxidation material layer; and
removing one part of the thin solid ozone layer, one part of the gate oxidation material layer and one part of gate electrode material layer that are formed above the source electrode and the drain electrode in order to respectively form a thin solid ozone boundary layer between the source electrode and the drain electrode and on the substrate body, a gate oxide layer being formed on a top surface of the thin solid ozone boundary layer, and a gate electrode being formed on a top surface of the gate oxide layer.

10. The method according to claim 9, wherein the substrate body is a silicon substrate.

11. The method according to claim 9, wherein the growth reaction equation of the solid ozone layer is 3Si+2O₃→3SiO₂.

12. The method according to claim 9, wherein the partial thin solid ozone layer, the partial gate oxidation material layer and the partial gate electrode material layer formed above the source electrode and the drain electrode are removed by etching.

13. The method according to claim 9, wherein the partial solid ozone layer is removed by etching.

14. The method according to claim 9, wherein before the step of continually pouring the deionized water on the top surface of the substrate unit, the method further comprises mixing chemical substances in the deionized water.
